(19) United States
(12) Patent Application Publication
(10) Pub. No.: US 2026/0196790 A1
(43) Pub. Date: Jul. 9, 2026

(54) GAS LASER DEVICE AND ELECTRONIC DEVICE MANUFACTURING METHOD

(71) Applicant: Gigaphoton Inc., Oyama-shi (JP)

(72) Inventor: Kohei KUSAYANAGI, Oyama-shi (JP)

(73) Assignee: Gigaphoton Inc., Oyama-shi (JP)

(21) Appl. No.: 19/404,905

(22) Filed: Dec. 1, 2025

(30) Foreign Application Priority Data
Jan. 7, 2025 (JP) 2025-002533

(51) Int. Cl. H01S 3/00; G03F 7/00; H01S 3/23

(52) U.S. Cl. CPC H01S 3/0057; G03F 7/70025; G03F 7/70041; G03F 7/70808; G03F 7/70975; H01S 3/0071; H01S 3/2308; H01S 3/2366

(57) ABSTRACT

A gas laser device includes a chamber device configured to output pulse laser light, and a pulse stretcher including a plurality of looped optical paths configured to extend a pulse width of the pulse laser light. Each of the looped optical paths includes a beam splitter on which the pulse laser light is incident and a plurality of orbit mirrors configured to sequentially reflect a part of the pulse laser light incident on the beam splitter and return the part of the pulse laser light to the beam splitter so as to be superimposed on another part of the pulse laser light. The pulse stretcher includes a unit that is detachable as separating two or more of the beam splitters from one or more of the orbit mirrors.

### CROSS-REFERENCE TO RELATED APPLICATIONS

The present application claims the benefit of Japanese Patent Application No. 2024/002533, filed on Jan. 7, 2025, the entire contents of which are hereby incorporated by reference.

### BACKGROUND

### 1. Technical Field

The present disclosure relates to a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

Since excimer laser light has a pulse width of about several 10 ns and a wavelength is short as 248 nm or 193 nm, excimer laser light is sometimes used for direct processing of a polymer material, a glass material, or the like. Chemical bonds in polymeric materials can be broken by excimer laser light having a photon energy higher than the bond energy. Therefore, it is known that non-heating processing of polymeric materials is possible with excimer laser light, and that the processing shape is beautiful. Further, it is known that, since glass, ceramics, and the like have high absorptance with respect to excimer laser light, even a material that is difficult to be processed with visible and infrared laser light can be processed with excimer laser light.

### LIST OF DOCUMENTS

### Patent Documents

Patent Document 1: International Publication No. WO2024/047867

Patent Document 2: Japanese Patent Application Publication No. 2000-088705

Patent Document 3: Japanese Patent Application Publication No. 2004-354408

### SUMMARY

A gas laser device according to an aspect of the present disclosure includes a chamber device configured to output pulse laser light, and a pulse stretcher including a plurality of looped optical paths configured to extend a pulse width of the pulse laser light. Each of the looped optical paths includes a beam splitter on which the pulse laser light is incident and a plurality of orbit mirrors configured to sequentially reflect a part of the pulse laser light incident on the beam splitter and return the part of the pulse laser light to the beam splitter so as to be superimposed on another part of the pulse laser light. The pulse stretcher includes a unit that is detachable as separating two or more of the beam splitters from one or more of the orbit mirrors.

An electronic device manufacturing method according to an aspect of the present disclosure includes outputting pulse laser light generated by a gas laser device to an exposure apparatus, and exposing a photosensitive substrate in the exposure apparatus to the pulse laser light output to the exposure apparatus to manufacture an electronic device. Here, the gas laser device includes a chamber device configured to output the pulse laser light, and a pulse stretcher including a plurality of looped optical paths configured to extend a pulse width of the pulse laser light. Each of the looped optical paths including a beam splitter on which the pulse laser light is incident and a plurality of orbit mirrors configured to sequentially reflect a part of the pulse laser light incident on the beam splitter and return the part of the pulse laser light to the beam splitter so as to be superimposed on another part of the pulse laser light. The pulse stretcher includes a unit that is detachable as separating two or more of the beam splitters from one or more of the orbit mirrors.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus used in an exposure process for an electronic device.

FIG. 2 is a schematic view showing a schematic configuration example of an entire gas laser device of a comparative example.

FIG. 3 is a schematic view of a schematic configuration example of a first light guide unit, a second light guide unit, and a pulse stretcher of the comparative example viewed obliquely from above.

FIG. 4 is a schematic view showing a schematic configuration example of a housing of the comparative example.

FIG. 5 is a schematic view of a schematic configuration example of the first light guide unit, the second light guide unit, and the pulse stretcher of a first embodiment viewed obliquely from above.

FIG. 6 is a schematic view showing a schematic configuration example of a unit of the first embodiment.

FIG. 7 is a schematic view showing the unit and the housing of the first embodiment.

FIG. 8 is a schematic view of a schematic configuration example of the first light guide unit, the second light guide unit, and the pulse stretcher of a modification of the first embodiment viewed obliquely from above.

FIG. 9 is a schematic view showing units and the housing of the modification of the first embodiment in the same manner as FIG. 7.

FIG. 10 is a schematic view of a schematic configuration example of the first light guide unit, the second light guide unit, and the pulse stretcher of a second embodiment viewed obliquely from above.

FIG. 11 is a schematic view of a schematic configuration example of the first light guide unit, the second light guide unit, and the pulse stretcher of a third embodiment viewed obliquely from above.

FIG. 12 is an enlarged schematic view showing a part of a looped optical path including a substrate and a beam splitter.

FIG. 13 is a schematic view of a schematic configuration example of the first light guide unit, the second light guide unit, and the pulse stretcher of a fourth embodiment viewed obliquely from above.

### DESCRIPTION OF EMBODIMENTS

1. Description of electronic device manufacturing apparatus used in exposure process for electronic device
2. Description of gas laser device of comparative example
2.1 Configuration
2.2 Operation
2.3 Problem
3. Description of gas laser device of first embodiment
3.1 Configuration
3.2 Maintenance method of pulse stretcher
3.3 Effect
3.4 Description of modification
4. Description of gas laser device of second embodiment
4.1 Configuration
4.2 Effect
5. Description of gas laser device of third embodiment
5.1 Configuration
5.2 Effect
6. Description of gas laser device of fourth embodiment
6.1 Configuration
6.2 Effect

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Electronic Device Manufacturing Apparatus Used in Exposure Process for Electronic Device

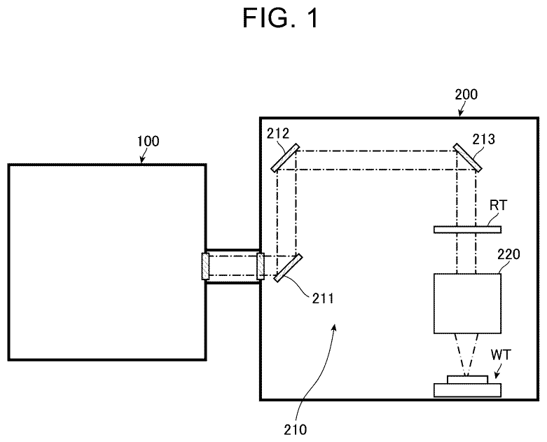

FIG. 1 is a schematic view showing a schematic configuration example of an entire electronic device manufacturing apparatus used in an exposure process for an electronic device. As shown in FIG. 1, the manufacturing apparatus used in the exposure process includes a gas laser device 100 and an exposure apparatus 200. The exposure apparatus 200 includes an illumination optical system 210 including a plurality of mirrors 211, 212, 213 and a projection optical system 220. The illumination optical system 210 illuminates a reticle pattern of a reticle stage RT with laser light incident from the gas laser device 100. The projection optical system 220 causes the laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 200 synchronously translates the reticle stage RT and the workpiece table WT to expose the workpiece to the laser light reflecting the reticle pattern. Through the exposure process as described above, a device pattern is transferred onto the semiconductor wafer, thereby a semiconductor device, which is the electronic device, can be manufactured.

### 2. Description of Gas Laser Device of Comparative Example

### 2.1 Configuration

The gas laser device of a comparative example will be described. The comparative example of the present disclosure is an example recognized by the applicant as known only by the applicant, and is not a publicly known example admitted by the applicant.

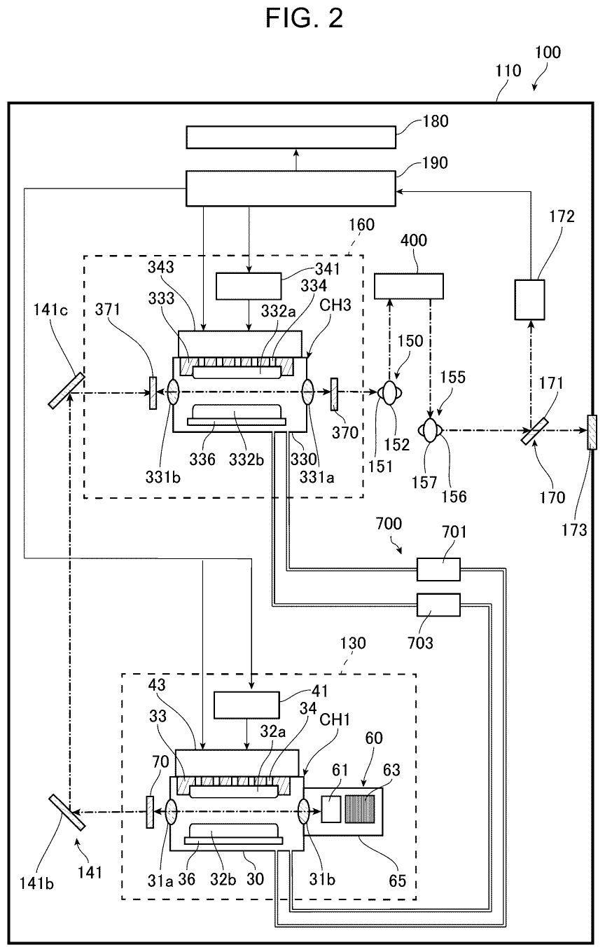

FIG. 2 is a schematic view showing a schematic configuration example of the entire gas laser device 100 of the comparative example. The gas laser device 100 is, for example, an ArF excimer laser device using a mixed gas including argon (Ar), fluorine (F₂), and neon (Ne). The gas laser device 100 outputs laser light having a center wavelength of about 193 nm. Here, the gas laser device 100 may be a gas laser device other than the ArF excimer laser device, and may be, for example, a KrF excimer laser device using a mixed gas including krypton (Kr), F₂, and Ne. In this case, the gas laser device 100 outputs laser light having a center wavelength of about 248 nm. The mixed gas containing Ar, F₂, and Ne which is a laser medium and the mixed gas containing Kr, F₂, and Ne which is a laser medium may be each referred to as a laser gas. In the mixed gas used in each of the ArF excimer laser device and the KrF excimer laser device, helium (He) may be used instead of Ne.

The gas laser device 100 includes a housing 110, and a laser oscillator 130 that is a master oscillator, an optical transmission unit 141, an amplifier 160 that is a power oscillator, a first light guide unit 150, a second light guide unit 155, a pulse stretcher 400, a detection unit 170, a display unit 180, a processor 190, and a gas module 700 arranged at an internal space of the housing 110 as a main configuration.

The laser oscillator 130 includes a chamber device CH1, a charger 41, a pulse power module 43, a line narrowing module 60, and an output coupling mirror 70 as a main configuration.

In FIG. 2, the internal configuration of the chamber device CH1 is shown as viewing from a direction substantially perpendicular to the travel direction of the laser light. The chamber device CH1 includes a housing 30, a pair of windows 31a, 31b, a pair of electrodes 32a, 32b, an insulating portion 33, a feedthrough 34, and an electrode holder portion 36 as a main configuration.

The housing 30 is supplied with the laser gas from a laser gas supply device 703 of the gas module 700 to the internal space of the housing 30 via a pipe, and the laser gas is enclosed at the internal space. The internal space is a space in which light is generated by excitation of the laser medium in the laser gas. This light travels to the windows 31a, 31b.

The window 31a is arranged at a wall surface of the housing 30 on the front side in the travel direction of the laser light from the gas laser device 100 to the exposure apparatus 200, and the window 31b is arranged at a wall surface of the housing 30 on the rear side in the travel direction. The windows 31a, 31b are calcium fluoride substrates, and surfaces of the windows 31a, 31b on the inner side and the outer side of the housing 30 are flat surfaces. Here, the windows 31a, 31b are not limited to the calcium fluoride substrates as long as being capable of transmitting the laser light.

The electrodes 32a, 32b are arranged to face each other at the internal space of the housing 30, and the longitudinal direction of the electrodes 32a, 32b is along the travel direction of the light generated by the high voltage applied between the electrode 32a and the electrode 32b. The space between the electrode 32a and the electrode 32b in the housing 30 is sandwiched by the window 31a and the window 31b. The electrodes 32a, 32b are discharge electrodes for exciting the laser medium by glow discharge. In the present example, the electrode 32a is the cathode and the electrode 32b is the anode.

The electrode 32a is supported by the insulating portion 33. The insulating portion 33 blocks an opening formed in the housing 30. The insulating portion 33 includes an insulator. Further, the feedthrough 34 made of a conductive member is arranged in the insulating portion 33. The feedthrough 34 applies a voltage, to the electrode 32a, supplied from the pulse power module 43. The electrode 32b is supported by the electrode holder portion 36 and is electrically connected to the electrode holder portion 36.

The charger 41 is a DC power source device that charges a capacitor (not shown) provided in the pulse power module 43 with a predetermined voltage. The charger 41 is arranged outside the housing 30 and is connected to the pulse power module 43. The pulse power module 43 includes a switch (not shown) controlled by the processor 190. The pulse power module 43 is a voltage application circuit that, when the switch is turned ON from OFF by the control, boosts the voltage applied from the charger 41 to generate a pulse high voltage, and applies the high voltage to the electrodes 32a, 32b. When the high voltage is applied, discharge occurs between the electrode 32a and the electrode 32b. The energy of the discharge excites the laser medium in the housing 30. When the excited laser gas shifts to a ground level, light is emitted, and the emitted light is transmitted through the windows 31a, 31b and is output to the outside of the housing 30. Since the pulse high voltage is applied between the electrode 32a and the electrode 32b by the pulse power module 43 as described above, the laser light is pulse laser light.

The windows 31a, 31b may be inclined at the Brewster angle with respect to the travel direction of the laser light so that P polarization of the laser light is suppressed from being reflected. In the present example, the windows 31a, 31b are inclined with respect to a direction perpendicular to the travel direction of the laser light and to a direction in which the electrodes 32a, 32b face each other. Therefore, the laser light output from the chamber device CH1 includes first linear polarization whose polarization direction is perpendicular to the direction in which the electrodes 32a, 32b face each other, and linear polarization whose polarization direction differs from the polarization direction of the first linear polarization is reduced from the laser light. That is, the windows 31a, 31b also serve as a polarizer that is inclined with respect to the polarization direction of the first linear polarization and reduces, from the laser light, the linear polarization whose polarization direction differs from the polarization direction of the first linear polarization.

The line narrowing module 60 includes a housing 65, and a prism 61, a grating 63, and a rotation stage (not shown) arranged at the internal space of the housing 65. An opening is formed in the housing 65, and the housing 65 is connected to the rear side of the housing 30 via the opening.

The prism 61 expands the beam width of the light output from the window 31b and causes the light to be incident on the grating 63. The prism 61 also reduces the beam width of the light reflected from the grating 63 and returns the light to the internal space of the housing 30 through the window 31b. The prism 61 is supported by the rotation stage and is rotated by the rotation stage. The incident angle of the light with respect to the grating 63 is changed by the rotation of the prism 61. Therefore, by rotating the prism 61, the wavelength of the light returning from the grating 63 to the housing 30 via the prism 61 can be selected. Although FIG. 2 shows an example in which one prism 61 is arranged, two or more prisms may be arranged.

The surface of the grating 63 is configured of a material having a high reflectance, and a large number of grooves are formed on the surface at predetermined intervals. The grating 63 is a dispersive optical element. The cross sectional shape of each groove is, for example, a right-angled triangle. The light incident on the grating 63 from the prism 61 is reflected by these grooves and diffracted in a direction corresponding to the wavelength of the light. The grating 63 is arranged in the Littrow arrangement, which causes the incident angle of the light incident on the grating 63 from the prism 61 to coincide with the diffraction angle of the diffracted light having a desired wavelength. Thus, light having a desired wavelength returns to the housing 30 via the prism 61.

The output coupling mirror 70 faces the window 31a, transmits a part of the laser light output from the window 31a, and reflects another part thereof to return to the internal space of the housing 30 through the window 31a. The output coupling mirror 70 is fixed to a holder (not shown) and is arranged at the internal space of the housing 110.

The grating 63 and the output coupling mirror 70 arranged with the housing 30 interposed therebetween configure a Fabry-Perot resonator, and the housing 30 is arranged on the optical path of the resonator. Accordingly, the resonator causes the light to resonate between both sides sandwiching the chamber device CH1.

The optical transmission unit 141 includes high reflection mirrors 141b, 141c as a main configuration. The high reflection mirrors 141b, 141c are fixed to respective holders (not shown) with inclination angles thereof adjusted, and are arranged at the internal space of the housing 110. The high reflection mirrors 141b, 141c highly reflects the laser light. The high reflection mirrors 141b, 141c are arranged on the optical path of the laser light from the output coupling mirror 70. The laser light is reflected by the high reflection mirrors 141b, 141c and travels to a rear mirror 371 of the amplifier 160. At least a part of the laser light is transmitted through the rear mirror 371.

The amplifier 160 amplifies the energy of the laser light output from the laser oscillator 130. The basic configuration of the amplifier 160 is substantially the same as that of the laser oscillator 130. In order to distinguish the components of the amplifier 160 from the components of the laser oscillator 130, the chamber device, the housing, the pair of windows, the pair of electrodes, the insulating portion, the feedthrough, the electrode holder portion, the charger, the pulse power module, and the output coupling mirror of the amplifier 160 are described as a chamber device CH3, a housing 330, a pair of window 331a, 331b, a pair of electrodes 332a, 332b, an insulating portion 333, a feedthrough 334, an electrode holder portion 336, a charger 341, a pulse power module 343, and an output coupling mirror 370. The electrodes 332a, 332b cause discharge for amplifying the laser light from the laser oscillator 130. The direction in which the electrodes 332a, 332b face each other is a direction perpendicular to the polarization direction of the first linear polarization in the laser light from the laser oscillator 130.

The windows 331a, 331b may be inclined with respect to the polarization direction of the first linear polarization so that the first linear polarization in the laser light is incident thereon as P polarization and an incident angle θ of the laser light becomes the Brewster angle. Owing to the inclination of the windows 331a, 331b, the laser light output from the chamber device CH3 includes first linear polarization, and linear polarization whose polarization direction differs from the first linear polarization is reduced from the laser light. That is, similarly to the windows 31a, 31b, the windows 331a, 331b also serve as a polarizer that is inclined with respect to the polarization direction of the first linear polarization and reduce, from the laser light, the linear polarization whose polarization direction differs from the polarization direction of the first linear polarization. The outer shape of the laser light output from the windows 331a, 331b may be a rectangular shape elongated in a direction in which the pair of electrodes 332a, 332b face each other. Similarly to the pulse power module 43, the pulse power module 343 is a voltage application circuit.

The amplifier 160 is mainly different from the laser oscillator 130 in that the line narrowing module 60 is not included and the rear mirror 371 is included.

The rear mirror 371 is provided between the high reflection mirror 141c and the window 331b and faces both thereof. The rear mirror 371 transmits a part of the laser light from the laser oscillator 130 toward the space between the electrodes 332a, 332b, and reflects the laser light amplified by the electrodes 332a, 332b toward the space between the electrodes 332a, 332b.

The output coupling mirror 370 is provided between the window 331a and a high reflection mirror 151 and faces both thereof. The output coupling mirror 370 reflects a part of the laser light amplified by and output through the electrodes 332a, 332b toward the space between the electrodes 332a, 332b, and transmits another part of the laser light toward the high reflection mirror 151. For this purpose, the surface of the output coupling mirror 370 facing the window 331a is coated with a partial reflection film having a predetermined reflectance.

The output coupling mirror 370 may have a circular shape. A surface facing the window 331a and a surface opposite thereto of the output coupling mirror 370 are flat surfaces. The configuration of the output coupling mirror 370 is similar to that of the output coupling mirror 70.

The rear mirror 371 and the output coupling mirror 370 arranged with the housing 330 interposed therebetween configure a resonator in which the laser light amplified by the electrodes 332a, 332b resonates. The housing 330 is arranged on the optical path of the resonator. The laser light output from the window 331a of the housing 330 is incident on the output coupling mirror 370 and a part of the laser light is reflected by the output coupling mirror 370. The laser light reflected by the output coupling mirror 370 returns to the internal space of the housing 330 via the window 331a, and is output from the window 331b. The laser light output from the window 331b is reflected by the rear mirror 371 and returns to the internal space of the housing 330 through the window 331b. Thus, the laser light output from the housing 330 reciprocates between the rear mirror 371 and the output coupling mirror 370. The reciprocating laser light is amplified every time the laser light passes through a discharge space between the electrode 332a and the electrode 332b. That is, the resonator causes light to resonate between both sides sandwiching the chamber device CH3, and the output coupling mirror 370 is arranged on one of the sides sandwiching the chamber device CH3. A part of the amplified laser light is transmitted through the output coupling mirror 370. The laser light transmitted through the output coupling mirror 370 travels to the high reflection mirror 151. As described above, the laser light traveling from the output coupling mirror 370 to the high reflection mirror 151 is pulse laser light.

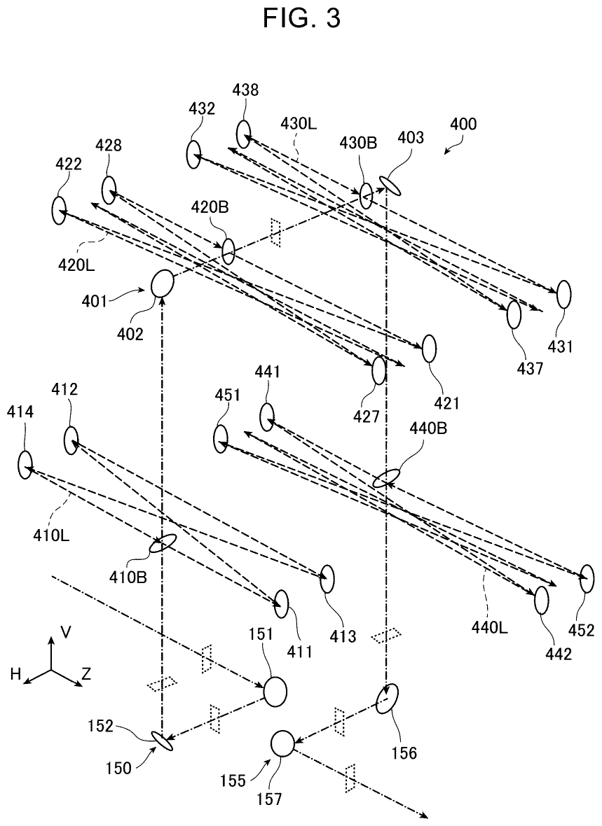

FIG. 3 is a schematic view of a schematic configuration example of the first light guide unit 150, the second light guide unit 155, and the pulse stretcher 400 of the comparative example viewed obliquely from above. The first light guide unit 150 includes high reflection mirrors 151, 152 as a main configuration. In the following, a direction in which the laser light propagates and which is parallel to the optical axis direction of the laser light output from the window 331a of the chamber device CH3 and transmitted through the output coupling mirror 370 is described as a Z direction, a height direction of the gas laser device 100 is described as a V direction, and a direction perpendicular to the V direction and the Z direction is described as an H direction. In the present example, the optical axis direction of the laser light output from the window 331a and transmitted through the output coupling mirror 370 is substantially parallel to the horizontal direction. Here, in the present example, the V-axis direction is parallel to the gravity direction.

The high reflection mirrors 151, 152 are fixed to respective holders (not shown) with inclination angles thereof adjusted, and highly reflect the laser light. In FIG. 3, the outer shape of the laser light is indicated by dotted lines. The high reflection mirrors 151, 152 are, for example, planar mirrors. The high reflection mirror 151 is arranged on the optical path of the laser light from the output coupling mirror 370, and reflects the laser light in the H direction. The high reflection mirror 152 is arranged on the optical path of the laser light reflected by the high reflection mirror 151, and reflects the laser light in the V direction. The laser light reflected by the high reflection mirror 152 enters the pulse stretcher 400.

The pulse stretcher 400 includes a plurality of optical elements, extends the pulse width of the laser light having entered the pulse stretcher 400 from the first light guide unit 150, and outputs the laser light whose pulse width has been extended toward the second light guide unit 155.

The pulse stretcher 400 of the present example includes a light guide optical system 401 and four looped optical paths 410L, 420L, 430L, 440L as a main configuration, and is arranged on the V direction side with respect to the optical axis of the laser light transmitted through the output coupling mirror 370.

The light guide optical system 401 of the present example includes two light guide mirrors 402, 403 that are optical elements as a main configuration. The light guide mirrors 402, 403 are fixed to respective holders (not shown) with inclination angles thereof adjusted, and highly reflect the laser light. The light guide mirrors 402, 403 are, for example, planar mirrors. The light guide mirror 402 is located on the H direction side with respect to the optical axis of the laser light transmitted through the output coupling mirror 370, and is arranged on the optical path of the laser light reflected by the high reflection mirror 152. The light guide mirror 402 reflects the laser light reflected by the high reflection mirror 152 in the −H direction. The light guide mirror 403 is arranged on the optical path of the laser light reflected by the light guide mirror 402 and on the −H direction side with respect to the optical axis of the laser light transmitted through the output coupling mirror 370. The light guide mirror 403 reflects the laser light reflected by the light guide mirror 402 in the −V direction, and the laser light is output from the pulse stretcher 400.

The looped optical path 410L of the present example includes a beam splitter 410B that is an optical element and four orbit mirrors 411, 412, 413, 414 that are separate optical elements. The beam splitter 410B is arranged on the optical path of the laser light having reflected by the high reflection mirror 152, having entered the pulse stretcher 400, and traveling toward the light guide mirror 402 among the optical paths of the laser light in the light guide optical system 401, and is fixed by a holder (not shown). The beam splitter 410B separates the incident laser light into two beams, transmits one separated beam toward the light guide mirror 402 to cause the one separated beam to propagate on the optical path of the light guide optical system 401, and reflects the other separated beam toward the orbit mirror 411.

The orbit mirrors 411 to 414 are, for example, concave mirrors, and are supported by holders (not shown), respectively. The orbit mirrors 411, 413 are arranged on the Z direction side with respect to the light guide mirrors 402, 403, and are aligned in the −H direction in the order of the orbit mirrors 411, 413. The orbit mirrors 412, 414 are arranged on the −Z direction side with respect to the light guide mirrors 402, 403, and are aligned in the H direction in the order of the orbit mirrors 412, 414. The orbit mirror 411 and the orbit mirror 414, and the orbit mirror 412 and the orbit mirror 413 face each other in a direction parallel to the Z direction. The beam splitter 410B is located between the orbit mirror 411 and the orbit mirror 414.

The orbit mirrors 411 to 414 sequentially reflect the laser light reflected by the beam splitter 410B in the order of the orbit mirrors 411, 412, 413, 414, and return the laser light to the beam splitter 410B. The laser light reflected by the orbit mirror 414 is incident on the beam splitter 410B from a surface opposite to the surface on which the laser light reflected by the high reflection mirror 152 is incident. Thus, the looped optical path 410L, which is an optical path of the laser light returning from the beam splitter 410B to the beam splitter 410B via the orbit mirrors 411 to 414, is formed, and the looped optical path 410L spreads in the H direction and the Z direction.

The beam splitter 410B reflects a part of the laser light reflected by the orbit mirror 414 and returned to the beam splitter 410B toward the light guide mirror 402, and transmits the other part toward the orbit mirror 411. The transmitted laser light propagates through the looped optical path 410L. Thus, the laser light is reflected four times in the looped optical path 410L to make one turn thereof, and circulates on the looped optical path 410L to make one or more turns.

The laser light returning to the beam splitter 410B after making one turn of the looped optical path 410L, separated by the beam splitter 410B, and traveling toward the light guide mirror 402 travels from the beam splitter 410B toward the light guide mirror 402 as being delayed by a predetermined time period as compared with the laser light traveling toward the light guide mirror 402 as being transmitted through the beam splitter 410B without traveling to the orbit mirror 411. The laser light traveling from the beam splitter 410B toward the light guide mirror 402 delayed by the predetermined time period overlaps a part of the laser light traveling toward the light guide mirror 402 as being transmitted through the beam splitter 410B without traveling to the orbit mirror 411. That is, the laser light returning to the beam splitter 410B is separated into laser light to overlap a part of one of the beams of the laser light having separated by the beam splitter 410B and laser light to be reflected sequentially by the orbit mirrors 411 to 414. The overlapping of the laser light occurs every time the laser light makes one turn of the looped optical path 410L, and the laser light having the pulse width extended by the overlapping of the laser light travels toward the light guide mirror 402 and propagates through the light guide optical system 401.

The looped optical path 420L of the present example includes a beam splitter 420B that is an optical element and eight orbit mirrors 421 to 428 that are separate optical elements. Here, in FIG. 3, only four orbit mirrors 421, 422, 427, 428 are shown, and four orbit mirrors 423 to 426 are omitted for easy viewing. The beam splitter 420B is arranged on the optical path of the laser light having reflected by the light guide mirror 402 and traveling toward the light guide mirror 403 among the optical paths of the laser light in the light guide optical system 401, and is fixed by a holder (not shown). The orbit mirrors 421 to 428 are, for example, concave mirrors, and are supported by holders (not shown), respectively. The orbit mirrors 421, 423, 425, 427 are arranged on the Z direction side with respect to the light guide mirrors 402, 403, and the orbit mirrors 422, 424, 426, 428 are arranged on the −Z direction side with respect to the light guide mirrors 402, 403. Similarly to the orbit mirrors 411 to 414 of the looped optical path 410L, the orbit mirrors 421 to 428 sequentially reflect a part of the laser light incident on the beam splitter 420B in the order of the orbit mirrors 421 to 428, and return the part of the laser light to the beam splitter 420B so as to be superimposed on another part of the laser light. Then, similarly to the looped optical path 410L, superimposition of the laser light occurs, and the laser light having the pulse width extended travels from the beam splitter 420B toward the light guide mirror 403 and propagates through the light guide optical system 401. The looped optical path 420L spreads in the H direction and the Z direction. The optical path length of the looped optical path 420L is longer than the optical path length of the looped optical path 410L. Further, the looped optical path 420L is located on the V direction side with respect to the looped optical path 410L, and the looped optical path 410L and the looped optical path 420L overlap each other in a direction parallel to the V direction.

The looped optical path 430L of the present example includes a beam splitter 430B that is an optical element and eight orbit mirrors 431 to 438 that are separate optical elements. Here, in FIG. 3, only four orbit mirrors 431, 432, 437, 438 are shown, and four orbit mirrors 433 to 436 are omitted for easy viewing. The beam splitter 430B is arranged on the optical path of the laser light traveling from the beam splitter 420B toward the light guide mirror 403 among the optical paths of the laser light in the light guide optical system 401, and is fixed by a holder (not shown). The orbit mirrors 431 to 438 are, for example, concave mirrors, and are supported by holders (not shown), respectively. The orbit mirrors 431, 433, 435, 437 are arranged on the Z direction side with respect to the light guide mirrors 402, 403, and the orbit mirrors 432, 434, 436, 438 are arranged on the −Z direction side with respect to the light guide mirrors 402, 403. Similarly to the orbit mirrors 411 to 414 of the looped optical path 410L, the orbit mirrors 431 to 438 sequentially reflect a part of the laser light incident on the beam splitter 430B in the order of the orbit mirrors 431 to 438, and return the part of the laser light to the beam splitter 430B so as to be superimposed on another part of the laser light. Then, similarly to the looped optical path 410L, superimposition of the laser light occurs, and the laser light having the pulse width extended travels from the beam splitter 430B toward the light guide mirror 403 and propagates through the light guide optical system 401. The looped optical path 430L spreads in the H direction and the Z direction. The optical path length of the looped optical path 430L is longer than the optical path length of the looped optical path 410L and is approximately the same as the optical path length of the looped optical path 420L. Further, the looped optical path 430L is located on the −H direction side with respect to the looped optical path 420L, and the looped optical path 420L and the looped optical path 430L overlap each other in a direction parallel to the H direction.

The looped optical path 440L of the present example includes a beam splitter 440B that is an optical element and twelve orbit mirrors 441 to 452 that are separate optical elements. Here, in FIG. 3, only four orbit mirrors 441, 442, 451, 452 are shown, and eight orbit mirrors 443 to 450 are omitted for easy viewing. The beam splitter 440B is arranged on the optical path of the laser light reflected by the light guide mirror 403 in the −V direction among the optical paths of the laser light in the light guide optical system 401, and is fixed by a holder (not shown). The beam splitter 440B separates the incident laser light into two beams, transmits one separated beam therethrough so that the one separated beam is output from the pulse stretcher 400 and travels toward the second light guide unit 155, and reflects the other separated beam toward the orbit mirror 441.

The orbit mirrors 441 to 452 are, for example, concave mirrors, and are supported by holders (not shown), respectively. The orbit mirrors 441, 443, 445, 447, 449, 451 are arranged on the Z direction side with respect to the light guide mirrors 402, 403, and the orbit mirrors 442, 444, 446, 448, 450, 452 are arranged on the-Z direction side with respect to the light guide mirrors 402, 403. Similarly to the orbit mirrors 411 to 414 of the looped optical path 410L, the orbit mirrors 441 to 452 sequentially reflect a part of the laser light incident on the beam splitter 440B in the order of the orbit mirrors 441 to 452, and return the part of the laser light to the beam splitter 440B so as to be superimposed on another part of the laser light. Then, similarly to the looped optical path 410L, superimposition of the laser light occurs, and the laser light having the pulse width extended propagates through the light guide optical system 401 toward the second light guide unit 155. The looped optical path 440L spreads in the H direction and the Z direction. The optical path length of the looped optical path 440L is longer than the optical path length of each of the looped optical paths 410L, 420L, 430L. The looped optical path 440L is located on the −V direction side with respect to the looped optical path 430L and on the −H direction side with respect to the looped optical path 410L. The looped optical path 430L and the looped optical path 440L overlap each other in a direction parallel to the V direction, and the looped optical path 410L and the looped optical path 440L overlap each other in a direction parallel to the H direction.

Thus, the light guide optical system 401 causes the laser light to be sequentially incident on the beam splitters 410B to 440B of the looped optical paths 410L to 440L. The optical path formed by the light guide optical system 401 is a non-looped optical path. The pulse width of the laser light is sequentially extended by the looped optical paths 410L to 440L. That is, the looped optical paths 410L, 420L, 430L, 440L are arranged in this order from the upstream side to the downstream side in the travel direction of the laser light. Then, the laser light whose pulse width has been extended is output from the pulse stretcher 400, and travels to the second light guide unit 155.

The second light guide unit 155 of the present example includes high reflection mirrors 156, 157 as a main configuration. The high reflection mirrors 156, 157 are fixed to respective holders (not shown) with inclination angles thereof adjusted, and highly reflect the laser light. The high reflection mirrors 156, 157 are, for example, planar mirrors. The high reflection mirror 156 is arranged on the optical path of the laser light output from the pulse stretcher 400, and is located on the −H direction side with respect to the optical axis of the laser light transmitted through the output coupling mirror 370. The high reflection mirror 156 reflects the laser light output from the pulse stretcher 400 in the H direction. The high reflection mirror 157 is arranged on the optical path of the laser light reflected by the high reflection mirror 156, and the high reflection mirror 157 and the high reflection mirror 151 are aligned in the V direction. The high reflection mirror 157 reflects the laser light reflected by the high reflection mirror 156 in the Z direction. The optical axis of the laser light traveling from the high reflection mirror 157 to the detection unit 170 may be non-parallel to the optical axis of the laser light being transmitted through the output coupling mirror 370.

The detection unit 170 includes a beam splitter 171 and an optical sensor 172 as a main configuration.

The beam splitter 171 is arranged on the optical path of the laser light output from the second light guide unit 155. The beam splitter 171 transmits the laser light output from the second light guide unit 155 toward an output window 173 with a high transmittance, and reflects a part of the laser light toward a light receiving surface of the optical sensor 172.

The optical sensor 172 measures a pulse energy of the laser light incident on the light receiving surface of the optical sensor 172. The optical sensor 172 is electrically connected to the processor 190, and outputs a signal indicating the measured pulse energy to the processor 190. The processor 190 controls the voltage to be applied to the electrodes 32a, 32b of the amplifier 160 based on the signal.

The output window 173 is provided in a wall of the housing 110. The light transmitted through the beam splitter 171 is output from the output window 173 to the exposure apparatus 200 outside the housing 110. The laser light is, for example, pulse laser light having a center wavelength of 193.4 nm.

The display unit 180 is a monitor that displays a state of control by the processor 190 based on a signal from the processor 190. The display unit 180 may be arranged outside the housing 110.

The processor 190 of the present disclosure is a processing device including a storage device in which a control program is stored and a central processing unit (CPU) that executes the control program. The processor 190 is specifically configured or programmed to perform various processes included in the present disclosure. The processor 190 controls the entire gas laser device 100. The processor 190 is electrically connected to an exposure processor (not shown) of the exposure apparatus 200, and transmits and receives various signals to and from the exposure processor.

The gas module 700 includes a laser gas exhaust device 701 and a laser gas supply device 703. The laser gas exhaust device 701 and the laser gas supply device 703 are electrically connected to the processor 190 with signal lines (not shown). The laser gas exhaust device 701 includes an exhaust pump (not shown), and exhausts the laser gas from the internal spaces of the housings 30, 330 via a pipe by suction of the exhaust pump according to a control signal from the processor 190. The laser gas supply device 703 supplies the laser gas from a laser gas supply source (not shown) arranged outside the housing 110 to the internal spaces of the housings 30, 330 via a pipe according to a control signal from the processor 190.

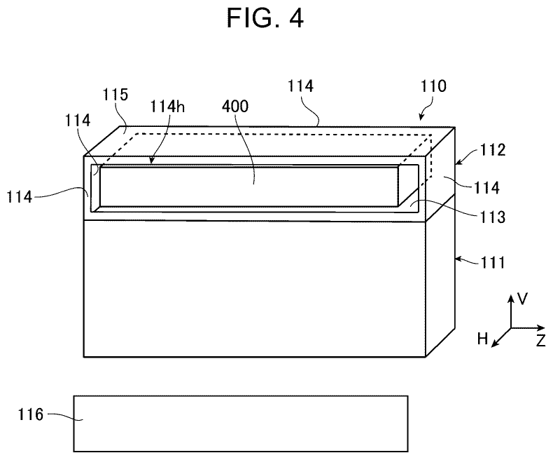

FIG. 4 is a schematic view showing a schematic configuration example of the housing 110 of the comparative example. As shown in FIG. 4, the housing 110 of the present example includes a first main body portion 111, a second main body portion 112, and a maintenance panel 116 as a main configuration. The first main body portion 111 is a box-shaped member having a space therein, and various devices such as the laser oscillator 130 and the amplifier 160 described above are accommodated at the internal space. In the present example, the shape of the first main body portion 111 is a rectangular parallelepiped shape elongated in the Z direction, and the first main body portion 111 includes four side walls, a lower wall, and an upper wall.

The second main body portion 112 is a box-shaped member having a space therein, and the pulse stretcher 400 is accommodated at the internal space. In the present example, the shape of the second main body portion 112 is a rectangular parallelepiped shape elongated in the Z direction, and the second main body portion 112 is arranged on the upper wall of the first main body portion 111. The second main body portion 112 includes a rectangular lower wall 113 elongated in the Z direction, four rectangular side walls 114 connected to four sides of the lower wall 113 respectively, and a rectangular upper wall 115 faced to the lower wall 113 and connected to the side walls 114. Two side walls 114 face each other in a direction parallel to the Z direction and are parallel to the H direction and the V direction. The other two side walls 114 face each other in a direction parallel to the H direction and are parallel to the Z direction and the V direction. Among the two side walls 114 facing each other in a direction parallel to the H direction, an opening 114h is formed in the side wall 114 located on the H direction side, and the pulse stretcher 400 accommodated at the internal space is accessible via the opening 114h. The outer shape of the opening 114h is a rectangular shape elongated in the Z direction, and the opening direction of the opening 114h is the H direction, which is the horizontal direction.

The maintenance panel 116 is a plate-shaped member that closes the opening 114h. The maintenance panel 116 is detachably attached to the second main body portion 112. FIG. 4 shows a state in which the maintenance panel 116 is removed from the second main body portion 112. Here, the opening 114h is not limited in the position and the shape as long as the pulse stretcher 400 can be taken in and out therethrough.

As described above, the laser light reflected by the high reflection mirror 152 in the V direction enters the pulse stretcher 400, and the laser light reflected by the light guide mirror 403 in the −V direction is output from the pulse stretcher 400. Therefore, in each of the upper wall of the first main body portion 111 and the lower wall 113 of the second main body portion 112, a through hole (not shown) through which the laser light reflected by the high reflection mirror 152 in the V direction passes and another through hole (not shown) through which the laser light reflected by the light guide mirror 403 in the −V direction passes are provided.

### 2.2 Operation

Next, operation of the gas laser device 100 of the comparative example will be described.

In a state before the gas laser device 100 outputs the laser light, the laser gas is supplied from the laser gas supply device 703 to the internal spaces of the housings 30, 330.

Before the gas laser device 100 outputs the laser light, the processor 190 receives a signal indicating a target energy Et and a signal indicating a light emission trigger from the exposure processor. The target energy Et is a target value of the energy of the laser light to be used in the exposure process. The processor 190 sets a predetermined charge voltage to the charger 41 so that an energy E becomes the target energy Et, and turns ON the switch of the pulse power module 43 in synchronization with the light emission trigger signal. Thus, the pulse power module 43 generates a pulse high voltage from the electric energy held in the charger 41, and applies the high voltage between the electrode 32a and the electrode 32b. When the high voltage is applied, discharge occurs between the electrode 32a and the electrode 32b, the laser medium contained in the laser gas between the electrode 32a and the electrode 32b is brought into an excited state, and light is emitted when the laser medium returns to the ground state. The emitted light resonates between the grating 63 and the output coupling mirror 70, and is amplified every time passing through the discharge space at the internal space of the housing 30, so that laser oscillation occurs. The laser light includes the first linear polarization, and linear polarization whose polarization direction differs from the first linear polarization is reduced from the laser light transmitted through the windows 31a, 31b. A part of the laser light is transmitted through the output coupling mirror 70, is reflected by the high reflection mirrors 141b, 141c, is transmitted through the rear mirror 371 and the window 331b, and travels into the housing 330.

The processor 190 turns ON the switch of the pulse power module 343 so that discharge occurs between the electrodes 332a, 332b when the laser light from the laser oscillator 130 travels to the discharge space in the housing 330. That is, the processor 190 controls the pulse power module 343 such that a high voltage is applied to the electrodes 332a, 332b after a predetermined delay time elapses from the timing at which the switch of the pulse power module 43 is turned ON.

Thus, the laser light having entered the amplifier 160 is amplified in the amplifier 160. Further, the laser light traveling to the internal space of the housing 330 is transmitted through the windows 331a, 331b as described above and travels to the rear mirror 371 and the output coupling mirror 370. Thus, the laser light having a predetermined wavelength reciprocates between the rear mirror 371 and the output coupling mirror 370. The laser light includes the first linear polarization, and linear polarization whose polarization direction differs from the first linear polarization is reduced from the laser light transmitted through the windows 331a, 331b. Further, the laser light is amplified every time passing through the discharge space at the internal space of the housing 330, and a part of the laser light becomes amplified laser light.

The amplified laser light from the amplifier 160 is transmitted through the output coupling mirror 370 and travels to the high reflection mirror 151. The laser light is reflected by the high reflection mirror 151 toward the high reflection mirror 152. The laser light reflected by the high reflection mirror 151 is reflected by the high reflection mirror 152 in the V direction and enters the pulse stretcher 400.

The laser light entering the pulse stretcher 400 is reflected by the light guide mirror 402 in the −H direction and travels to the light guide mirror 403. The laser light is reflected by the light guide mirror 403 in the −V direction and output from the pulse stretcher 400. Further, in the pulse stretcher 400, the pulse width of the laser light that propagates as being reflected sequentially by the light guide mirrors 402, 403 of the light guide optical system 401 in this manner is extended by the respective looped optical paths 410L to 440L. Then, the laser light whose pulse width has been extended is output from the pulse stretcher 400, and travels to the high reflection mirror 156. The laser light is reflected by the high reflection mirror 156 toward the high reflection mirror 157. The laser light reflected by the high reflection mirror 156 is reflected by the high reflection mirror 157 in the Z direction and travels to the beam splitter 171.

A part of the laser light having traveled to the beam splitter 171 is transmitted through the beam splitter 171 and the output window 173 and travels to the exposure apparatus 200, while another part is reflected by the beam splitter 171 and travels to the optical sensor 172.

The optical sensor 172 measures the energy E of the received laser light. The optical sensor 172 outputs a signal indicating the measured energy E to the processor 190. The processor 190 performs feedback control on the charge voltages of the chargers 41, 341 so that a difference ΔE between the energy E and the target energy Et is within an allowable range.

### 2.3 Problem

In the looped optical paths 410L to 440L of the pulse stretcher, the beam splitters repeat transmission and reflection of the pulse laser light. Therefore, the beam splitters 410B to 440B are more likely to be deteriorated and the replacement frequency thereof tends to be higher than the orbit mirrors 411 to 414, 421 to 428, 431 to 438, 441 to 452. There is a demand for facilitating the replacement of the beam splitters 410B to 440B having a high replacement frequency as described above to facilitate maintenance.

Therefore, in the following embodiments, a gas laser device capable of facilitating maintenance is exemplified.

### 3. Description of Gas Laser Device of First Embodiment

Next, the gas laser device 100 of a first embodiment will be described. Any component same as that described above is denoted by an identical reference sign, and duplicate description thereof is omitted unless specific description is needed.

### 3.1 Configuration

The pulse stretcher 400 of the present embodiment is mainly different from the pulse stretcher 400 of the comparative example in including a unit that is detachable as separating two or more beam splitters from one or more mirrors.

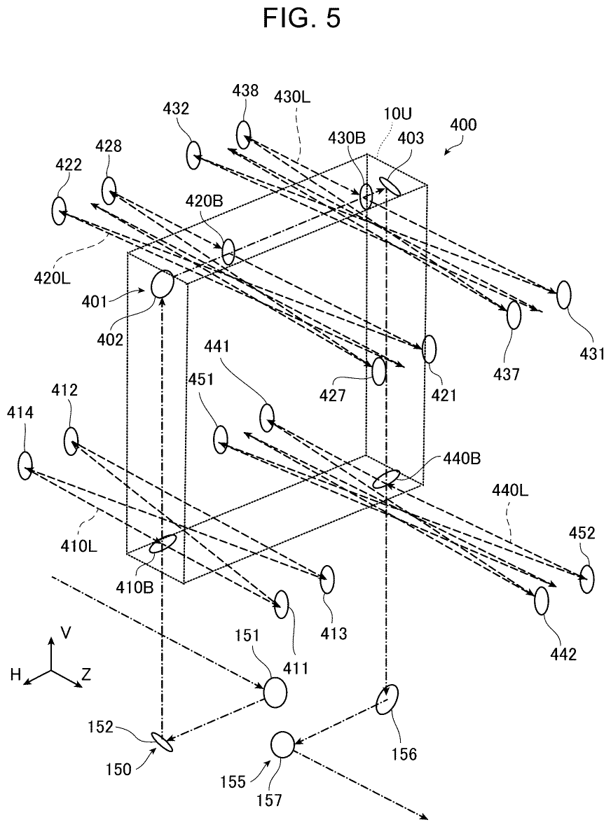

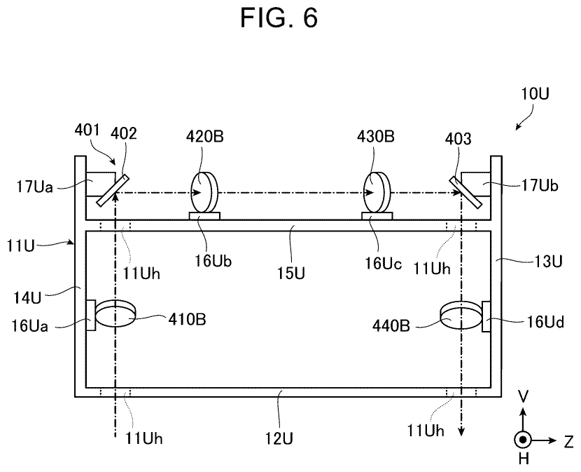

FIG. 5 is a schematic view of a schematic configuration example of the first light guide unit 150, the second light guide unit 155, and the pulse stretcher 400 of the present embodiment viewed obliquely from above. FIG. 6 is a schematic view showing a schematic configuration example of a unit 10U of the present embodiment. As shown in FIGS. 5 and 6, in the present embodiment, the pulse stretcher 400 includes one unit 10U, and the unit 10U includes all the beam splitters 410B to 440B, all light guide mirrors 402, 403, and a frame 11U as a main configuration. The unit 10U does not include the orbit mirrors 411 to 414, 421 to 428, 431 to 438, 441 to 452 configuring the looped optical paths 410L to 440L. In FIG. 5, the frame 11U is omitted.

The frame 11U is a member that supports the beam splitters 410B to 440B and the light guide mirrors 402, 403. The frame 11U of the present embodiment includes four support plates 12U to 15U. The support plate 12U is a plate-shaped member extending in a direction parallel to the Z direction. The support plate 13U is a plate-shaped member extending in the V direction from an end portion of the support plate 12U on the Z direction side. The support plate 14U is a plate-shaped member extending in the V direction from an end portion of the support plate 12U on the −Z direction side. The support plate 15U is a plate-shaped member that is located on the support plate 12U side with respect to end portions of the support plates 13U, 14U in the V direction side, faces the support plate 12U, and is connected to the support plates 13U, 14U.

The beam splitter 410B is fixed to a holder 16Ua fixed to the support plate 14U at a position between the support plates 12U, 15U with the tilt angle thereof adjusted. The beam splitters 420B, 430B are fixed to holders 16Ub, 16Uc fixed to the support plate 15U on an opposite side of the support plate 12U with the tilt angles thereof adjusted. The beam splitter 440B is fixed to a holder 16Ud fixed to the support plate 13U at a position between the support plates 12U, 15U with the tilt angle thereof adjusted. The light guide mirror 402 is fixed to a holder 17Ua fixed to the support plate 14U at a position on the V direction side with respect to the support plate 15U with the tilt angle thereof adjusted. The light guide mirror 403 is fixed to a holder 17Ub fixed to the support plate 13U at a position on the V direction side with respect to the support plate 15U with the tilt angle thereof adjusted. Through holes 11Uh through which the laser light from the high reflection mirror 152 toward the light guide mirror 402 and the laser light from the light guide mirror 403 toward the high reflection mirror 156 pass are formed in each of the support plates 12U, 15U.

Thus, the beam splitters 410B to 440B and the light guide mirrors 402, 403 are supported on the frame 11U. Here, the frame 11U is not limited to the above as long as supporting the beam splitters 410B to 440B and the light guide mirrors 402, 403.

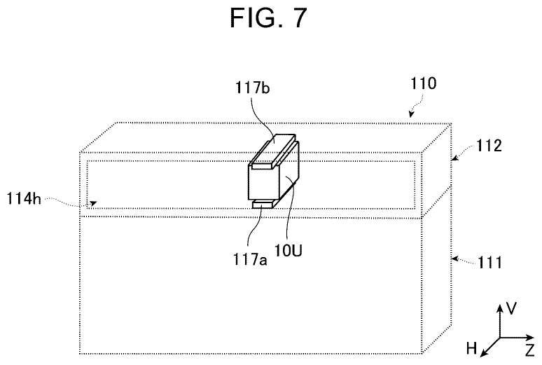

FIG. 7 is a schematic view showing the unit 10U and the housing 110 of the present embodiment. In FIG. 7, the first main body portion 111 and the second main body portion 112 of the housing 110 are indicated by dotted lines, and the maintenance panel 116 is omitted. As shown in FIG. 7, the second main body portion 112 includes two movement mechanisms 117a, 117b. The unit 10U is held by the movement mechanisms 117a, 117b. The movement mechanisms 117a, 117b can move the unit 10U to be taken in and out via the opening 114h. The movement mechanisms 117a, 117b are configured by, for example, a rail extending in a direction parallel to the H direction, and the movement direction of the unit 10U being held is a direction parallel to the H direction, which is the horizontal direction. The unit 10U held by the movement mechanisms 117a, 117b is positioned in a direction parallel to the H direction by a positioning mechanism (not shown) including a pin, a V-groove, and the like, and is fixed by a fixing mechanism (not shown) such as a bolt. The opening 114h may be smaller than the opening shown in FIG. 4 as long as the area and the shape thereof allow the unit 10U to be taken in and out therethrough. Correspondingly, the maintenance panel 116 may also be smaller than that in FIG. 4. Alternatively, the maintenance panel 116 may be provided with an opening having an area and a shape that allow the unit 10U to be taken in and out therethrough, and a small maintenance panel capable of closing the opening may be arranged.

### 3.2 Maintenance Method of Pulse Stretcher

Next, a maintenance method of the pulse stretcher 400 and a maintenance method of the beam splitters 410B to 440B of the first embodiment will be described.

In the present embodiment, the timing at which maintenance of the beam splitters 410B to 440B is performed is determined in advance. This timing is determined by, for example, the number of times the pulse laser light is output from the gas laser device 100. The processor 190 counts the number of output times, and causes the display unit 180 to display a sign indicating maintenance when the number of output times reaches a predetermined number of output times. When the sign is displayed, an operator performs maintenance of the beam splitters 410B to 440B.

Here, the timing at which maintenance of the beam splitters 410B to 440B is performed may be determined by a factor other than the number of output times, and may be determined based on, for example, operation time of the gas laser device 100.

The operator stops operation of the gas laser device 100 and removes the maintenance panel 116 from the second main body portion 112. Next, the fixing mechanism fixing the unit 10U is released, and the unit 10U is taken out from the second main body portion 112 via the opening 114h using the movement mechanisms 117a, 117b. Thus, the beam splitters 410B to 440B are separated from the orbit mirrors 411 to 414, 421 to 428, 431 to 438, 441 to 452 and taken out. Next, the beam splitters 410B to 440B of the unit 10U and the light guide mirrors 402, 403 are replaced. Here, only the beam splitters 410B to 440B may be replaced, or the unit 10U taken out may be replaced with a new unit 10U. Next, the unit 10U is accommodated in the accommodation space of the second main body portion 112 via the opening 114h using the movement mechanisms 117a, 117b, positioned by the positioning mechanism, and fixed by the fixing mechanism. Next, after the maintenance panel 116 is attached to the second main body portion 112 to close the opening 114h, the gas laser device 100 is operated.

### 3.3 Effect

As described above, the beam splitters 410B to 440B are more likely to be deteriorated and the replacement frequency thereof tends to be higher than the orbit mirrors 411 to 414, 421 to 428, 431 to 438, 441 to 452. The pulse stretcher 400 of the present embodiment includes the unit 10U that is detachable as separating the four beam splitter 410B to 440B from the orbit mirrors 411 to 414, 421 to 428, 431 to 438, 441 to 452. Therefore, the four beam splitter 410B to 440B that tend to have a higher replacement frequency can be easily taken out as compared with a case in which the beam splitters 410B to 440B and the orbit mirrors 411 to 414, 421 to 428, 431 to 438, 441 to 452 are taken out. Therefore, according to the gas laser device 100 of the present embodiment, replacement of the four beam splitters 410B to 440B can be easily performed and maintenance can be easily performed.

In the pulse stretcher 400 of the present embodiment, the unit 10U includes all the beam splitters 410B to 440B. Therefore, replacement of all the beam splitters 410B to 440B can be easily performed simultaneously.

The pulse stretcher 400 of the present embodiment includes two light guide mirrors 402, 403, and further includes the light guide optical system 401 that causes the pulse laser light to be incident sequentially on the beam splitters 410B to 440B of the four looped optical paths 410L to 440L. Therefore, it is possible to improve the degree of freedom in arrangement of the four looped optical paths 410L to 440L as compared with a case in which the light guide optical system 401 is not included.

In the pulse stretcher 400 of the present embodiment, the unit 10U includes all the light guide mirrors 402, 403. Therefore, maintenance of the beam splitters 410B to 440B and maintenance of the light guide optical system 401 can be performed simultaneously. Here, the unit 10U may not include at least one of the light guide mirrors 402, 403.

The gas laser device 100 of the present embodiment further includes the housing 110 including the second main body portion 112 that accommodates the pulse stretcher 400 and has the opening 114h through which the unit 10U can be taken in and out, and the movement mechanisms 117a, 117b capable of moving the unit 10U to be taken in and out via the opening 114h. Therefore, according to the gas laser device 100 of the present embodiment, the unit 10U can be easily taken in and out. Here, the housing 110 may not include the movement mechanisms 117a, 117b.

In the gas laser device 100 of the present embodiment, the movement direction of the unit 10U by the movement mechanisms 117a, 117b is the horizontal direction. Therefore, when the unit 10U is taken in and out, unintentional movement of the unit 10U due to its own weight can be suppressed. Here, the movement direction of the unit 10U by the movement mechanisms 117a, 117b may be non-parallel to the horizontal direction.

In the gas laser device 100 of the present embodiment, the housing 110 further includes the maintenance panel 116 that closes the opening 114h and is attached to the second main body portion 112 in a detachably attachable manner. Accordingly, it is possible to suppress dust and the like from entering the accommodation space of the second main body portion 112, and it is possible to reduce the influence of dust and the like on the pulse laser light, for example, even in a case that a case accommodating the pulse stretcher 400 is not provided.

### 3.4 Description of Modification

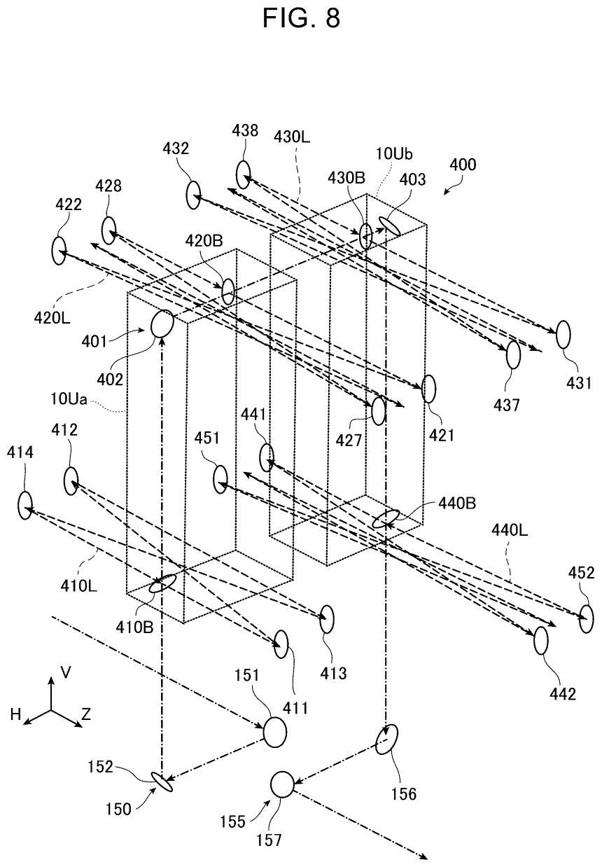

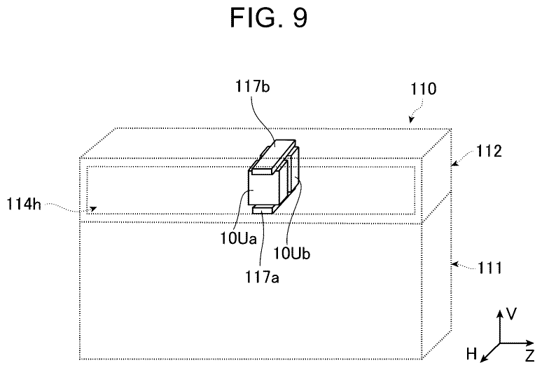

Next, the gas laser device 100 of a modification of the first embodiment will be described. FIG. 8 is a schematic view of a schematic configuration example of the first light guide unit 150, the second light guide unit 155, and the pulse stretcher 400 of the present modification viewed obliquely from above. FIG. 9 is a schematic view showing units and the housing 110 of the present modification in the same manner as FIG. 7. As shown in FIGS. 8 and 9, the pulse stretcher 400 of the present modification is mainly different from the pulse stretcher 400 of the first embodiment in that the unit 10U is divided into two units 10Ua, 10Ub.

The unit 10Ua includes the beam splitters 410B, 420B of the looped optical paths 410L, 420L, the light guide mirror 402, and a frame (not shown) as a main configuration. The beam splitters 410B, 420B and the light guide mirror 402 are located on the H direction side with respect to the optical axis of the laser light transmitted through the output coupling mirror 370. The beam splitters 410B, 420B and the light guide mirror 402 are supported by the frame with the tilt angles thereof adjusted.

The unit 10Ub includes the beam splitters 430B, 440B of the looped optical paths 430L, 440L, the light guide mirror 403, and a frame (not shown) as a main configuration. The beam splitters 430B, 440B and the light guide mirror 403 are located on the −H direction side with respect to the optical axis of the laser light transmitted through the output coupling mirror 370. The beam splitters 430B, 440B and the light guide mirror 403 are supported by the frame with the tilt angles thereof adjusted.

In the present modification, the unit 10Ua is located on the opening 114h side with respect to the unit 10Ub, and overlaps the unit 10Ub in a direction parallel to the opening direction of the opening 114h. Further, the looped optical paths 410L, 420L are arranged on the upstream side of the looped optical paths 430L, 440L. Therefore, the beam splitters 410B, 420B of the unit 10Ua are arranged on the upstream side of the beam splitters 430B, 440B of the unit 10Ub in the travel direction of the laser light.

Similarly to the unit 10U of the first embodiment, the units 10Ua, 10Ub are held by the movement mechanisms 117a, 117b, and the movement mechanisms 117a, 117b can move the units 10Ua, 10Ub to be taken in and out via the opening 114h. Further, the units 10Ua, 10Ub are positioned in a direction parallel to the H direction by a positioning mechanism (not shown) including a pin, a V-groove, and the like, and is fixed by a fixing mechanism (not shown) such as a bolt.

Next, the maintenance method of the pulse stretcher 400 of the present modification will be described. In the present modification, the timing of performing maintenance is determined in advance for each unit 10Ua, 10Ub, and the timing is determined by the number of output times of the pulse laser light. The maintenance frequency of the unit 10Ua is higher than the maintenance frequency of the unit 10Ub.

In the present modification, the number of output times when maintenance of the unit 10Ub is performed is twice the number of output times when maintenance of the unit 10Ua is performed. Therefore, when maintenance of the unit 10Ub is performed, maintenance of the unit 10Ua is also performed. The maintenance frequency of the unit 10Ua is not limited as long as it is higher than the maintenance frequency of the unit 10Ub. The timing of performing maintenance of each of the units 10Ua, 10Ub may be set so that maintenance of the unit 10Ua is not performed when maintenance of the unit 10Ub is performed. Further, the timing at which maintenance is performed may be determined by a factor other than the number of output times, and may be determined based on, for example, operation time of the gas laser device 100.

First, maintenance of the unit 10Ua will be described. Similarly to maintenance of the unit 10U in the first embodiment, the operator stops operation of the gas laser device 100 and removes the maintenance panel 116 from the second main body portion 112. Next, the unit 10Ua is taken out from the second main body portion 112. Thus, the beam splitters 410B, 420B are separated from the orbit mirrors 411 to 414, 421 to 428, 431 to 438, 441 to 452 and taken out. The beam splitters 410B, 420B of the unit 10Ua and the light guide mirror 402 are replaced. Here, only the beam splitters 410B, 420B may be replaced, or the unit 10Ua taken out may be replaced with a new unit 10Ua. Next, the unit 10Ua is accommodated in the accommodation space of the second main body portion 112, positioned by the positioning mechanism, and fixed by the fixing mechanism. After the opening 114h is closed by the maintenance panel 116, the gas laser device 100 is operated.

Next, maintenance of the unit 10Ub will be described. Similarly to maintenance of the unit 10Ua, the operator stops operation of the gas laser device 100 and removes the maintenance panel 116 from the second main body portion 112. Then, as described above, the unit 10Ua is taken out from the second main body portion 112. Next, the fixing mechanism for fixing the unit 10Ub is released, and the unit 10Ub is taken out from the second main body portion 112. Thus, the beam splitters 430B, 440B are separated from the orbit mirrors 411 to 414, 421 to 428, 431 to 438, 441 to 452 and taken out. The beam splitters 430B, 440B of the unit 10Ub and the light guide mirror 403 are replaced. Here, only the beam splitters 430B, 440B may be replaced, or the unit 10Ub taken out may be replaced with a new unit 10Ub. Then, the unit 10Ub is accommodated in the accommodation space of the second main body portion 112, positioned by the positioning mechanism, and fixed by the fixing mechanism.

In the present modification, the beam splitters 410B, 420B and the light guide mirror 402 of the unit 10Ua are replaced as well, and the unit 10Ua is accommodated in the accommodation space of the second main body portion 112 and fixed. In a case that maintenance of the unit 10Ua is not performed at the timing of maintenance of the unit 10Ub, the taken-out unit 10Ua is accommodated in the accommodation space of the second main body portion 112 and fixed without being replaced.

After the units 10Ua, 10Ub are accommodated in the accommodation space of the second main body portion 112 and fixed as described above, the maintenance panel 116 is attached to the second main body portion 112 to close the opening 114h, and the gas laser device 100 is operated.

The pulse stretcher 400 of the present embodiment includes the units 10Ua, 10Ub. The unit 10Ua includes the beam splitters 410B, 420B and is detachable as being separated from the orbit mirrors 411 to 414, 421 to 428, 431 to 438, 441 to 452. The unit 10Ub includes the beam splitters 430B, 440B and is detachable as being separated from the orbit mirrors 411 to 414, 421 to 428, 431 to 438, 441 to 452. Therefore, replacement of the beam splitters 410B, 420B and the beam splitters 430B, 440B can be easily performed at different timings.

In the travel direction of the laser light, optical elements arranged on the upstream side tend to deteriorate more easily. This is because the pulse width of the laser light at the upstream side is shorter than the pulse width of the laser light at the downstream side, and the intensity of the laser light at the upstream side is higher than the intensity of the laser light at the downstream side. In the gas laser device 100 of the present modification, the unit 10Ua is located on the opening 114h side with respect to the unit 10Ub. The beam splitters 410B, 420B of the unit 10Ua are arranged on the upstream side with respect to the beam splitters 430B, 440B of the unit 10Ub in the travel direction of the laser light. Therefore, the unit 10Ub including the beam splitters 410B, 420B that tend to have a higher replacement frequency can be accessed more easily than a case in which the unit 10b is located on the opening 114h side with respect to the unit 10Ua. Therefore, according to the gas laser device 100 of the present modification, replacement of the beam splitters 410B, 420B that tend to have a higher replacement frequency can be easily performed and maintenance can be easily performed. From this viewpoint, the unit 10Ua may include the beam splitters 410B to 430B, and the unit 10Ub may include the beam splitter 440B.

### 4. Description of Gas Laser Device of Second Embodiment

Next, the gas laser device 100 of a second embodiment will be described. Any component same as that described above is denoted by an identical reference sign, and duplicate description thereof is omitted unless specific description is needed. Further, in some drawings, a part of a member may be omitted or simplified for easy viewing.

### 4.1 Configuration

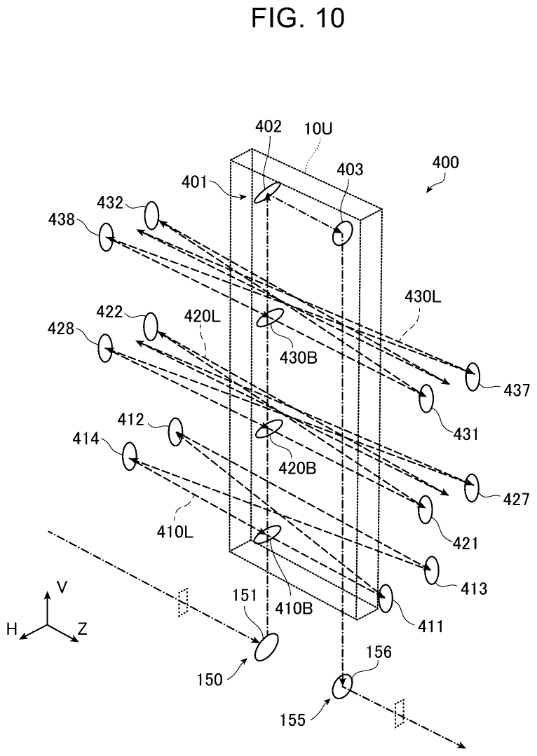

FIG. 10 is a schematic view of a schematic configuration example of the first light guide unit 150, the second light guide unit 155, and the pulse stretcher 400 of the present embodiment viewed obliquely from above. As shown in FIG. 10, the gas laser device 100 of the present embodiment is mainly different from the gas laser device 100 of the first embodiment in that the first light guide unit 150 does not include the high reflection mirror 152, the pulse stretcher 400 does not include the looped optical path 440L, and the second light guide unit 155 does not include the high reflection mirror 157.

In the first light guide unit 150 of the present embodiment, the high reflection mirror 151 is arranged on the optical path of the laser light from the output coupling mirror 370, reflects the laser light in the V direction, and the laser light reflected by the high reflection mirror 151 enters the pulse stretcher 400.

In the pulse stretcher 400 of the present embodiment, the light guide mirror 402 of the light guide optical system 401 is arranged on the optical path of the laser light reflected by the high reflection mirror 151, and reflects the laser light reflected by the high reflection mirror 151 in the Z direction. The light guide mirror 403 is arranged on the optical path of the laser light reflected by the light guide mirror 402, and reflects the laser light reflected by the light guide mirror 402 in the −V direction, and the laser light is output from the pulse stretcher 400.

In the present embodiment, the beam splitters 410B to 430B of the looped optical paths 410L to 430L are arranged in the order of the beam splitters 410B, 420B, 430B on the optical path of the laser light reflected by the high reflection mirror 151 and traveling toward the light guide mirror 402. Therefore, the beam splitters 410B to 430B are arranged in the order of the beam splitters 410B, 420B, 430B in the V direction, which is parallel to the gravity direction, and the looped optical paths 410L to 430L are arranged in the order of the looped optical paths 410L, 420L, 430L in the V direction. The pulse width of the laser light is sequentially extended by the looped optical paths 410L to 430L, the laser light is output from the pulse stretcher 400, and travels to the second light guide unit 155.

In the second light guide unit 155 of the present embodiment, the high reflection mirror 156 is arranged on the optical path of the laser light reflected by the light guide mirror 403, and reflects the laser light output from the pulse stretcher 400 in the Z direction, and the laser light travels to the beam splitter 171.

The unit 10U of the present embodiment includes the beam splitters 410B to 430B, the light guide mirrors 402, 403, and a frame (not shown). The frame supports the beam splitters 410B to 430B and the light guide mirrors 402, 403. Similarly to the unit 10U of the first embodiment, the unit 10U is detachable as being separated from the orbit mirrors 411 to 414, 421 to 428, 431 to 438.

### 4.2 Effect

In the pulse stretcher 400 of the present embodiment, the looped optical paths 410L to 430L are arranged side by side in the gravity direction. Therefore, according to the gas laser device 100 of the present embodiment, it is possible to suppress the pulse stretcher 400 from becoming large in the horizontal direction.

In the pulse stretcher 400 of the present embodiment, the beam splitters 410B to 430B are arranged side by side in the gravity direction. Therefore, according to the gas laser device 100 of the present embodiment, it is possible to suppress the design of the pulse stretcher 400 from becoming complicated. Here, the beam splitters 410B to 430B may not be arranged side by side in the gravity direction. For example, the beam splitter 430B may be arranged on the optical path of the laser light reflected by the light guide mirror 403.

### 5. Description of Gas Laser Device of Third Embodiment

Next, the gas laser device 100 of a third embodiment will be described. Any component same as that described above is denoted by an identical reference sign, and duplicate description thereof is omitted unless specific description is needed. Further, in some drawings, a part of a member may be omitted or simplified for easy viewing.

### 5.1 Configuration

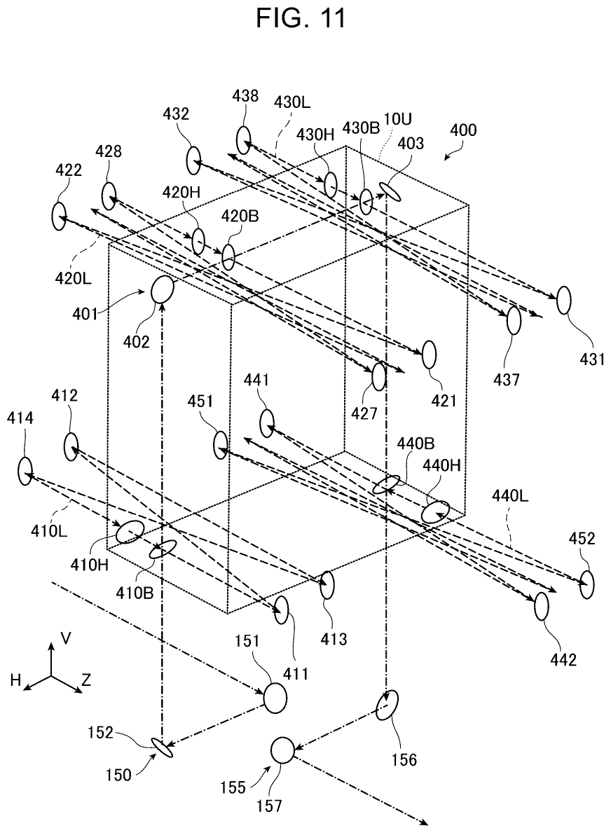

FIG. 11 is a schematic view of a schematic configuration example of the first light guide unit 150, the second light guide unit 155, and the pulse stretcher 400 of the present embodiment viewed obliquely from above. As shown in FIG. 11, the pulse stretcher 400 of the present embodiment is mainly different from the pulse stretcher 400 of the first embodiment in that the looped optical paths 410L to 440L further include optically transmissive flat plate-shaped substrates 410H to 440H, respectively.

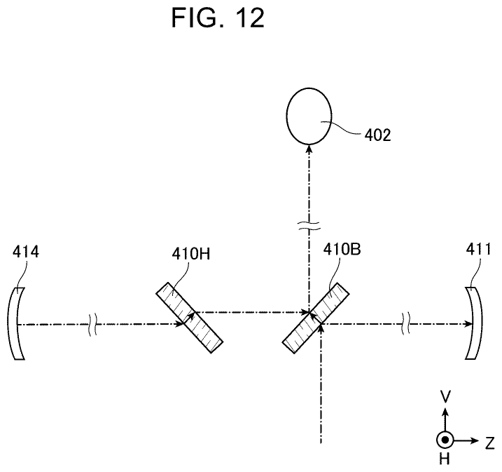

FIG. 12 is an enlarged schematic view showing a part of the looped optical path 410L including the substrate 410H and the beam splitter 410B. The substrate 410H is arranged on the optical path of the laser light reflected by the orbit mirror 414 and returning to the beam splitter 410B obliquely with respect to the optical path. Specifically, the substrate 410H is arranged so as to be plane-symmetric with the beam splitter 410B with respect to a plane perpendicular to the optical path of the laser light reflected by the orbit mirror 414 and returning to the beam splitter 410B. The thickness and refractive index of the substrate 410H are approximately the same as the thickness and refractive index of the beam splitter 410B. A section of the looped optical path 410L from the beam splitter 410B to the substrate 410H is located on a plane perpendicular to the V direction. The substrate 410H shifts the optical path of the laser light reflected by the orbit mirror 414 and returning to the beam splitter 410B in the V direction, and superimposes the laser light on the laser light traveling from the beam splitter 410B toward the light guide mirror 402.

Similarly to the substrate 410H, the substrate 420H is arranged on the optical path of the laser light reflected by the orbit mirror 428 and returning to the beam splitter 420B obliquely with respect to the optical path. Then, the substrate 420H superimposes the laser light returning to the beam splitter 420B on the laser light traveling from the beam splitter 420B toward the light guide mirror 403.

Similarly to the substrate 410H, the substrate 430H is arranged on the optical path of the laser light reflected by the orbit mirror 438 and returning to the beam splitter 430B obliquely with respect to the optical path. Then, the substrate 430H superimposes the laser light returning to the beam splitter 430B on the laser light traveling from the beam splitter 430B toward the light guide mirror 403.

Similarly to the substrate 410H, the substrate 440H is arranged on the optical path of the laser light reflected by the orbit mirror 452 and returning to the beam splitter 440B obliquely with respect to the optical path. Then, the substrate 440H superimposes the laser light returning to the beam splitter 440B on the laser light traveling from the beam splitter 440B toward the high reflection mirror 156.

Examples of the substrates 410H to 440H include a calcium fluoride substrate. Here, the substrates 410H to 440H are not limited to the above as long as being arranged obliquely with respect to the optical path of the laser light returning to the beam splitters 410B to 440B to guide the laser light so that the laser light is superimposed on another part of the laser light being incident on the beam splitters 410B to 440B. For example, the thickness and refractive index of the substrates 410H to 440H may be different from the thickness and refractive index of the beam splitters 410B to 440B.

The unit 10U of the present embodiment includes the beam splitters 410B to 440B, the substrates 410H to 440H, the light guide mirrors 402, 403, and a frame (not shown). The frame supports the beam splitters 410B to 440B, the substrates 410H to 440H, and the light guide mirrors 402, 403. Similarly to the unit 10U of the first embodiment, the unit 10U is detachable as being separated from the orbit mirrors 411 to 414, 421 to 428, 431 to 438, 441 to 452.

### 5.2 Effect

In the pulse stretcher 400 of the present embodiment, the looped optical paths 410L to 440L include the optically transmissive substrates 410H to 440H. The substrates 410H to 440H are arranged obliquely with respect to the optical path of the laser light that is a part of the laser light incident on the beam splitters 410B to 440B and returning to the beam splitters 410B to 440B. Then, the substrates 410H to 440H guide the laser light to be superimposed on another part of the laser light incident on the beam splitters 410B to 440B. Therefore, a section of the looped optical paths 410L to 440L from the beam splitters 410B to 440B to the substrates 410H to 440H may be located on a plane. Therefore, it is possible to suppress the design of the looped optical paths 410L to 440L from becoming complicated.

In the pulse stretcher 400 of the present embodiment, the unit 10U includes all the substrates 410H to 440H. Therefore, replacement of all the substrates 410H to 440H can be easily performed simultaneously. Here, the unit 10U may not include at least one of the substrates 410H to 440H.

### 6. Description of Gas Laser Device of Fourth Embodiment

Next, the gas laser device 100 of a fourth embodiment will be described. Any component same as that described above is denoted by an identical reference sign, and duplicate description thereof is omitted unless specific description is needed. Further, in some drawings, a part of a member may be omitted or simplified for easy viewing.

### 6.1 Configuration

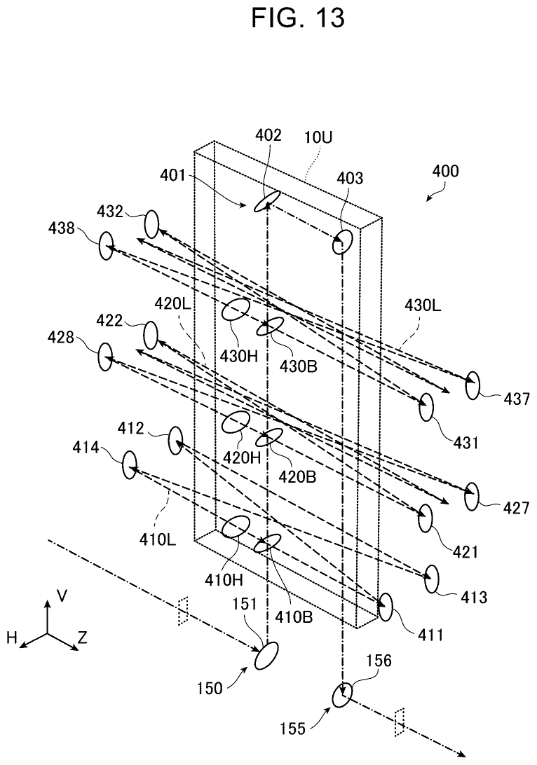

FIG. 13 is a schematic view of a schematic configuration example of the first light guide unit 150, the second light guide unit 155, and the pulse stretcher 400 of the present embodiment viewed obliquely from above. As shown in FIG. 13, the pulse stretcher 400 of the present embodiment is mainly different from the pulse stretcher 400 of the second embodiment in that the looped optical paths 410L to 430L further include optically transmissive flat plate-shaped substrates 410H to 430H, respectively.

Similarly to the substrate 410H of the third embodiment, the substrate 410H is arranged on the optical path of the laser light reflected by the orbit mirror 414 and returning to the beam splitter 410B obliquely with respect to the optical path. Then, the substrate 410H superimposes the laser light returning to the beam splitter 410B on the laser light traveling from the beam splitter 410B toward the light guide mirror 402.

Similarly to the substrate 420H, 430H of the third embodiment, the substrate 420H, 430H is arranged on the optical path of the laser light reflected by the orbit mirror 428, 438 and returning to the beam splitter 420B, 430B obliquely with respect to the optical path. Then, the substrate 420H, 430H superimposes the laser light returning to the beam splitter 420B, 430B on the laser light traveling from the beam splitter 420B, 430B toward the light guide mirror 402.

The unit 10U of the present embodiment includes the beam splitters 410B to 430B, the substrates 410H to 430H, the light guide mirrors 402, 403, and a frame (not shown). The frame supports the beam splitters 410B to 430B, the substrates 410H to 430H, and the light guide mirrors 402, 403. Similarly to the unit 10U of the second embodiment, the unit 10U is detachable as being separated from the orbit mirrors 411 to 414, 421 to 428, 431 to 438.

### 6.2 Effect

In the pulse stretcher 400 of the present embodiment, the looped optical paths 410L to 430L include the optically transmissive substrates 410H to 430H. The substrates 410H to 430H are arranged obliquely with respect to the optical path of the laser light that is a part of the laser light incident on the beam splitters 410B to 430B and returning to the beam splitters 410B to 430B. Then, the substrates 410H to 430H guide the laser light so as to be superimposed on another part of the laser light incident on the beam splitters 410B to 430B. Therefore, similarly to the gas laser device 100 of the third embodiment, a section of the looped optical paths 410L to 430L from the beam splitters 410B to 430B to the substrates 410H to 430H may be located on a plane. Therefore, it is possible to suppress the design of the looped optical paths 410L to 430L from becoming complicated.

In the pulse stretcher 400 of the present embodiment, the unit 10U includes all the substrates 410H to 430H. Therefore, similarly to the gas laser device 100 of the third embodiment, replacement of all the substrates 410H to 430H can be easily performed simultaneously. Here, the unit 10U may not include at least one of the substrates 410H to 430H.

Although the above embodiments have been described as an example, the present disclosure is not limited thereto and can be modified as appropriate.

In the first embodiment and the third embodiment described above, the pulse stretcher 400 including the unit 10U having four beam splitters 410B to 440B has been described as an example, and in the second embodiment the fourth embodiment described above, the pulse stretcher 400 including the unit 10U having three beam splitters 410B to 430B has been described as an example. However, the pulse stretcher 400 is only required to include a unit that is detachable as separating two or more beam splitters from one or more orbit mirrors. For example, the unit 10U may include a part of the orbit mirrors 411 to 414, 421 to 428, 431 to 438, 441 to 452.

Further, in the modification of the first embodiment described above, the unit 10Ua including the beam splitters 410B, 420B arranged on the upstream side of the beam splitters 430B, 430B of the unit 10Ub in the travel direction of the laser light and located on the opening 114h side has been described as an example. However, it is only required that at least one of the units 10Ua, 10Ub includes two or more beam splitters. For example, the unit 10Ua may include the beam splitters 410B, 420B, 430B and the unit 10Ub may include the beam splitter 440B.

Further, in the first embodiment and the third embodiment described above, the pulse stretcher 400 including four looped optical paths 410L to 440L has been described as an example, and in the second embodiment and the fourth embodiment described above, the pulse stretcher 400 including three looped optical paths 410L to 430L has been described as an example. However, the number of the looped optical paths is only required to be two or more.

Further, in the above embodiments, the looped optical path 410L in which the number of the orbit mirrors is four, the looped optical path 420L in which the number of the orbit mirrors is eight, the looped optical path 430L in which the number of the orbit mirrors is eight, and the looped optical path 440L in which the number of the orbit mirrors is twelve have been described as an example. However, the number of the orbit mirrors configuring each looped optical path is not limited. Here, it is preferable that the looped optical path arranged on the downstream side in the travel direction of the pulse laser light has a larger number of the orbit mirrors.

Further, in the above embodiments, the light guide optical system 401 configured by two light guide mirrors 402, 403 has been described as an example. However, the number of the light guide mirrors configuring the light guide optical system 401 is not limited. Further, the pulse stretcher 400 may not include the light guide optical system 401.

In the first and third embodiments described above, the first light guide unit 150 including the two high reflection mirrors 151, 152 and the second light guide unit 155 including the two high reflection mirrors 156, 157 have been described as an example. However, as long as the laser light output from the chamber device CH3 enters the pulse stretcher 400, the number of high reflection mirrors included in each of the first light guide unit 150 and the second light guide unit 155 is not limited. Further, the gas laser device 100 may not include at least one of the first light guide unit 150 and the second light guide unit 155.

Further, in the above embodiments, the housing 110 including the first main body portion 111 and the second main body portion 112 arranged on the upper wall of the first main body portion 111 has been described as an example. However, the arrangement of the second main body portion 112 is not limited. For example, the second main body portion 112 may be arranged below the first main body portion 111. Further, the first main body portion 111 may also serve as the second main body portion 112. That is, the pulse stretcher 400 is simply required to be arranged in the accommodation space of the first main body portion 111. Further, the opening direction of the opening 114h is not limited. For example, the opening 114h may be formed in the upper wall 115 of the second main body portion 112.

Further, in the above-described embodiments, the beam splitters 410B to 440B causing the reflected laser light to propagate to the looped optical paths 410L to 440L respectively have been described as an example. However, the laser light transmitted through the beam splitters 410B to 440B may propagate to the looped optical paths 410L to 440L respectively. In this case, the beam splitters 410B to 440B serve as a part of the light guide optical system 401, and the beam splitters 410B to 440B serve for both the light guide optical system 401 and the looped optical paths 410L to 440L.

In the above-described embodiments, the gas laser device 100 including the laser oscillator 130 and the amplifier 160 have been exemplified. However, the gas laser device 100 may not include the amplifier 160. In this case, for example, the laser light output from the chamber device CH1 and transmitted through the output coupling mirror 70 enters the pulse stretcher 400.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. A gas laser device comprising:
a chamber device configured to output pulse laser light; and
a pulse stretcher including a plurality of looped optical paths configured to extend a pulse width of the pulse laser light,
each of the looped optical paths including a beam splitter on which the pulse laser light is incident and a plurality of orbit mirrors configured to sequentially reflect a part of the pulse laser light incident on the beam splitter and return the part of the pulse laser light to the beam splitter so as to be superimposed on another part of the pulse laser light, and
the pulse stretcher including a unit that is detachable as separating two or more of the beam splitters from one or more of the orbit mirrors.

2. The gas laser device according to claim 1,
further comprising a housing including a main body portion that accommodates the pulse stretcher and has an opening through which the unit is to be taken in and out, and a movement mechanism capable of moving the unit to be taken in and out via the opening.

3. The gas laser device according to claim 2,
wherein an opening direction of the opening is the horizontal direction, and
a movement direction of the unit by the movement mechanism is the horizontal direction.

4. The gas laser device according to claim 2,
wherein the housing further includes a maintenance panel that closes the opening and is attached to the main body portion in a detachably attachable manner.

5. The gas laser device according to claim 1,
wherein the unit includes all the beam splitters.

6. The gas laser device according to claim 1,
wherein the pulse stretcher further includes a light guide optical system that includes a plurality of light guide mirrors, and causes the pulse laser light to be incident sequentially on the beam splitters of the plurality of looped optical paths, and
the unit includes at least one of the light guide mirrors.

7. The gas laser device according to claim 6,
wherein the unit includes all the light guide mirrors.

8. The gas laser device according to claim 1,
wherein each of the looped optical paths further includes an optically transmissive substrate that is arranged obliquely with respect to an optical path of the part of the pulse laser light returning to the beam splitter, and guides the part of the pulse laser light so as to be superimposed on the other part of the pulse laser light, and
the unit includes the substrate.

9. The gas laser device according to claim 8,
wherein the unit includes all the substrates.

10. The gas laser device according to claim 1,
wherein the orbit mirrors are concave mirrors.

11. The gas laser device according to claim 1,
wherein the plurality of looped optical paths are arranged side by side in the gravity direction.

12. The gas laser device according to claim 11,
wherein the beam splitters in the plurality of looped optical paths arranged side by side in the gravity direction are arranged side by side in the gravity direction.

13. The gas laser device according to claim 1,
wherein a number of the looped optical paths is three or more, and
the pulse stretcher includes a beam splitter different from the beam splitter included in the unit, and includes another unit that is detachable as separating the different beam splitter from one or more of the orbit mirrors.

14. The gas laser device according to claim 13,
further comprising a housing including a main body portion that accommodates the pulse stretcher and has an opening through which the unit and the other unit are to be taken in and out,
wherein the unit is located on an opening side with respect to the other unit, and
the beam splitter of the unit is arranged on an upstream side with respect to the beam splitter of the other unit in a travel direction of the pulse laser light.

15. An electronic device manufacturing method, comprising:
outputting pulse laser light generated by a gas laser device to an exposure apparatus; and
exposing a photosensitive substrate in the exposure apparatus to the pulse laser light output to the exposure apparatus to manufacture an electronic device,
the gas laser device including:
a chamber device configured to output the pulse laser light; and
a pulse stretcher including a plurality of looped optical paths configured to extend a pulse width of the pulse laser light,
each of the looped optical paths including a beam splitter on which the pulse laser light is incident and a plurality of orbit mirrors configured to sequentially reflect a part of the pulse laser light incident on the beam splitter and return the part of the pulse laser light to the beam splitter so as to be superimposed on another part of the pulse laser light, and
the pulse stretcher including a unit that is detachable as separating two or more of the beam splitters from one or more of the orbit mirrors.
